(19) United States
(12) Patent Application Publication
(10) Pub. No.: US 2007/0212829 A1
(43) Pub. Date: Sep. 13, 2007

(54) Method of manufacturing a semiconductor device

(76) Inventors: Masashi Takahashi, Tsukuba-shi (JP); Toshihide Nabatame, Tsukuba-shi (JP); Hideki Satake, Chigasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/715,354

(22) Filed: Mar. 8, 2007

(30) Foreign Application Priority Data
Mar. 10, 2006 (JP) 2006-065513

(51) Int. Cl. H01L 21/8238

(52) U.S. Cl. 438/216; 257/E21.637; 257/E21.625

(57) ABSTRACT

A method of manufacturing an MIS semiconductor device includes forming a high dielectric film on a main surface of a semiconductor substrate, forming a silicon film on the high dielectric film, annealing the semiconductor substrate after the silicon film is formed, processing the high dielectric film and the silicon film into a gate pattern after the semiconductor substrate is annealed, to form a gate insulating film and a gate electrode, and forming source and drain regions on the main surface of the semiconductor substrate using the gate electrode as a mask.

### CROSS-REFERENCE TO RELATED APPLICATIONS

This application is based upon and claims the benefit of priority from prior Japanese Patent Application No. 2006-065513, filed Mar. 10, 2006, the entire contents of which are incorporated herein by reference.

### BACKGROUND OF THE INVENTION

1. Field of the Invention

The present invention relates to a method of manufacturing an MIS semiconductor device using a high dielectric gate insulating film (high-k gate insulating film).

2. Description of the Related Art

Metal oxide semiconductor field-effect transistors (MOSFETs) have recently scaled in size as in accordance with a high degree of integration of integrated circuits. Accordingly, the gate oxide films of the transistors tend to decrease in area. The smaller the area of a gate oxide film, the thinner the film has to be formed. However, if the gate oxide film is thinned, there occurs a problem in which leakage current is increased by quantum tunneling effect.

A technique of using a high dielectric film as a gate insulator has already been developed as one for resolving the above problem (JP-A 2005-243678 (KOKAI)). The high dielectric gate insulator is also referred to as a high-k gate insulator and means an insulator whose dielectric constant k is greater than that of a silicon oxide film. Using the high dielectric gate insulating film, the thickness of a gate insulating film can be increased with the dielectric constant which is equal to or greater than the silicon oxide film, thereby suppressing quantum tunneling effect. For example, an oxide film of hafnium (Hf) or zirconium (Zr) is known as the high dielectric gate insulator.

Conventionally, in manufacturing a semiconductor device having a high dielectric gate insulator such as a metal insulator semiconductor filed-effect transistor (MISFET), annealing (post deposition anneal: PDA) was performed at a temperature of 700° C. to 950° C. immediately after the high dielectric gate insulating film is formed (JP-A 2005-243678 (KOKAI)). This is done to improve the performance of the high dielectric gate insulator by packing a high dielectric film closely, eliminating impurities, etc.

It is thought that if a semiconductor integrated circuit decreases in size further, its high dielectric gate insulating film has to decrease in thickness. If, however, the high dielectric gate insulating film is thinned further, there occur problems of a large gate leakage current and reduction of carrier mobility. When PDA is used as an annealing method, there occurs a problem of an increase of equivalent oxide thickness (which is obtained by converting the thickness of a high dielectric film into that of a silicon oxide film having the same electrical characteristic as that of the high dielectric film) due to the residual oxygen in an annealing apparatus.

### BRIEF SUMMARY OF THE INVENTION

According to an embodiment of the present invention, there is provided a method of manufacturing an MIS semiconductor device, comprising forming a high dielectric film on a main surface of a semiconductor substrate, forming a silicon film on the high dielectric film, annealing the semiconductor substrate after the silicon film is formed, processing the high dielectric film and the silicon film into a gate pattern after the semiconductor substrate is annealed, to form a gate insulating film and a gate electrode, and forming source and drain regions on the main surface of the semiconductor substrate using the gate electrode as a mask.

### BRIEF DESCRIPTION OF THE SEVERAL VIEWS OF THE DRAWING

FIGS. 1A to 1D are cross sectional views illustrating a process of manufacturing an MIS semiconductor device according to a first embodiment, the sectional views being taken in the direction of a channel length of the device;

FIG. 2 is a graph showing a relationship between annealing temperature and electron mobility to describe the first embodiment;

FIG. 3 is a graph showing a relationship between annealing temperature and gate leakage current to describe the first embodiment;

FIG. 4 is a graph showing a relationship between annealing temperature and equivalent oxide thickness to describe the first embodiment;

FIG. 5 is a graph showing a relationship between annealing temperature and interface state to describe the first embodiment;

FIG. 6 is a graph showing a relationship between annealing temperature and electron mobility to describe the first embodiment; and

FIGS. 7A to 7D are cross sectional views illustrating a process of manufacturing an MIS semiconductor device according to a second embodiment, the cross sectional views being taken in the direction of a channel length of the device.

### DETAILED DESCRIPTION OF THE INVENTION

Embodiments of the present invention will be described with reference to the accompanying drawings. In the drawings, the respective components are shown schematically and their dimensions, shapes and configuration are provided to such a degree that the invention can be understood. The numerical values indicated below are each merely an example.

### First Embodiment

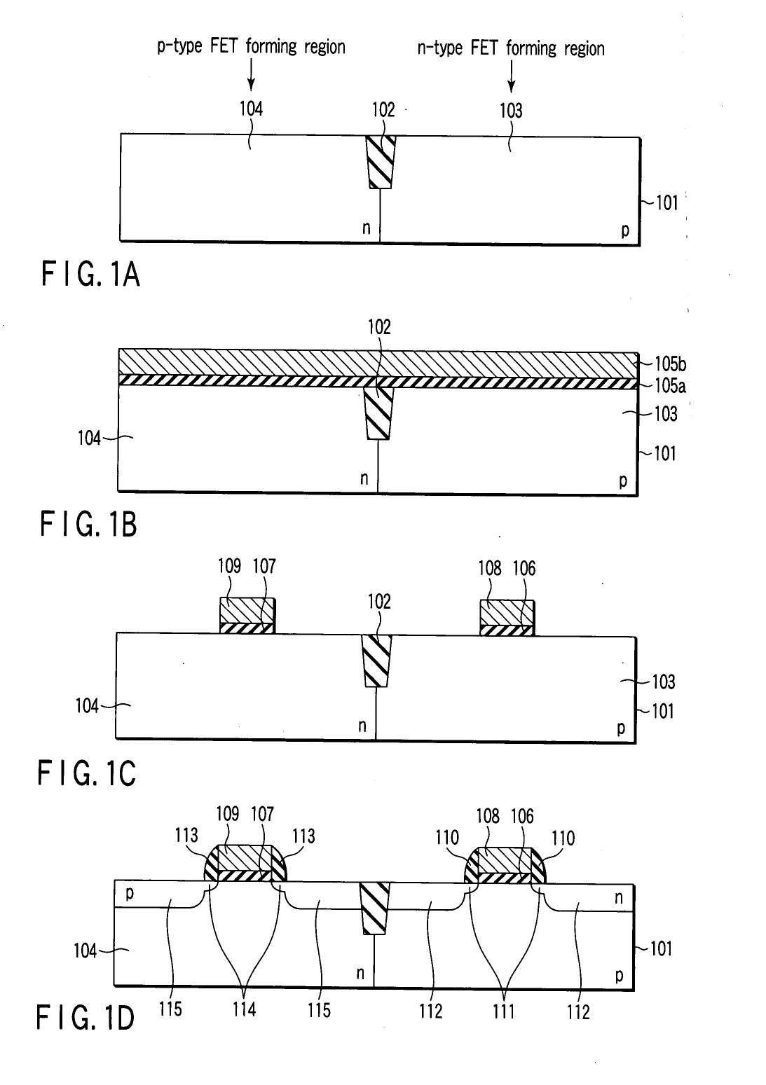

There will be described a process of manufacturing an MIS semiconductor device according to a first embodiment in conjunction with FIGS. 1A to 1D.

(1) As shown in FIG. 1A, at first, a shallow trench isolation (STI) region 102 is formed in a surface area of a semiconductor substrate 101 using a normal process technology. Then, impurities are introduced into the substrate to form a p-well (n-MISFET forming region) 103 and an n-well (p-MISFET forming region) 104.

(2) And then, as shown in FIG. 1B, a high dielectric film (high-k film) 105a having a thickness of, e.g., 1.6 nm to 3 nm is formed on the entire surface of the semiconductor substrate 101. For example, HfAlO can be used as the high-k film 105a, but the high-k film 105a is not always limited to HfAlO. After that, a polysilicon film 105b having a thickness of, e.g., 10 nm is formed on the surface of the high-k film 105a using a normal deposition technology.

(3) Then, the semiconductor substrate 101 is annealed by a rapid thermal anneal (RTA) apparatus, for example. In the first embodiment, the annealing temperature is set at 1000° C. to 1050° C. for the reason described below. The annealing time is, for example, 10 to 30 sec. The RTA apparatus is an annealing apparatus for annealing a semiconductor substrate by heat from an infrared lamp and has the features of increasing and decreasing the temperature at high speed and controlling the temperature with high reliability. In the first embodiment, annealing is performed after the high-k film 105a is covered with the polysilicon film 105b, so that the equivalent oxide thickness of a gate insulating film can be prevented from increasing by the residual oxygen.

For example, a flash lamp anneal (FLA) apparatus and a laser anneal (LA) apparatus can be used as the annealing apparatus. The FLA apparatus has a xenon flash lamp and the LA apparatus employs a laser beam. When these apparatuses are used, the annealing temperature can be set at 1000° C. to 1150° C. and the annealing time can be set at 0.1 msec to 10 msec.

(4) Next, as shown in FIG. 1C, the high-k film 105a and polysilicon film 105b are processed to have a gate pattern to thereby form high dielectric gate insulating films 106 and 107 and polysilicon gate electrodes 108 and 109. More specifically, ions are implanted into the semiconductor substrate 101 in order to set a threshold voltage and then a polysilicon film 105b of, e.g., 100 nm is deposited again on the substrate. After that, the high-k film 105a and polysilicon film 105b have only to be patterned.

(5) As shown in FIG. 1D, the p-well 103 is doped with low-concentration n-type impurities to form an n-type extension region 111 and then a sidewall 110 that covers either side of each of the high dielectric gate insulating film 106 and polysilicon gate electrodes 108. After that, the p-well 103 is doped with high-concentration n-type impurities to form a high-concentration n-type impurity region 112. At the same time, the polysilicon gate electrode 108 is doped with the n-type impurities.

Similarly, in the n-well 104, a sidewall 113 that covers either side of each of the high dielectric gate insulating film 107 and polysilicon gate electrodes 109, a p-type extension region 114, and a high-concentration p-type impurity region 115 are formed, and the polysilicon gate electrodes 109 is doped with p-type impurities.

(6) Then, activation annealing is performed for the semiconductor substrate 101 using an RTA apparatus, for example. There are no specific conditions for the activation annealing, but it is normally done at high temperature for a short time (0.1 second or shorter). If the activation annealing is performed independently of the annealing in the above step (3), the conditions can be optimized according to the objective of the annealing.

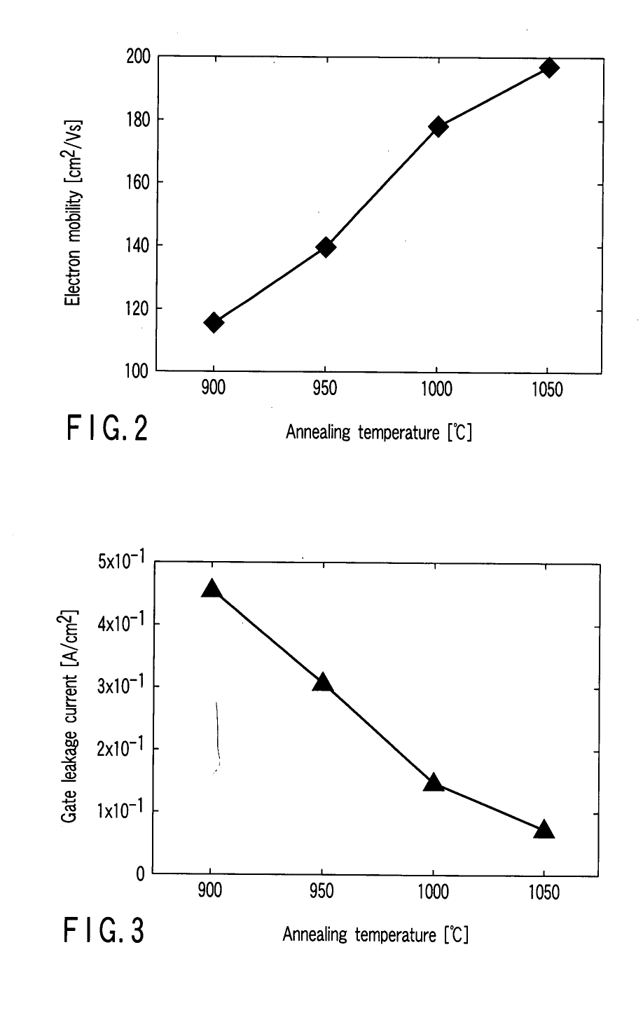

The reason why the annealing temperature ranges from 1000° C. to 1050° C. in the above step (3) will be described in FIGS. 2 to 6.

In FIG. 2 showing a relationship between annealing temperature and electron mobility in the above step (3), the horizontal axis indicates the annealing temperature [° C.] and the vertical axis indicates the electron mobility [cm²/Vs]. As is well-known, it is desirable that the electron mobility should be high in field effect transistors (FETs). It is found that the electron mobility improves as the annealing temperature increases in the FET according to the first embodiment in FIG. 2.

In FIG. 3 showing a relationship between annealing temperature and gate leakage current in the above step (3), the horizontal axis indicates the annealing temperature [° C.] and the vertical axis indicates the gate leakage current [A/cm²]. As is well-known, it is desirable that the gate leakage current should be small in field effect transistors (FETs). It is clear that the gate leakage current characteristic improves as the annealing temperature increases in the FET according to the first embodiment in FIG. 3.

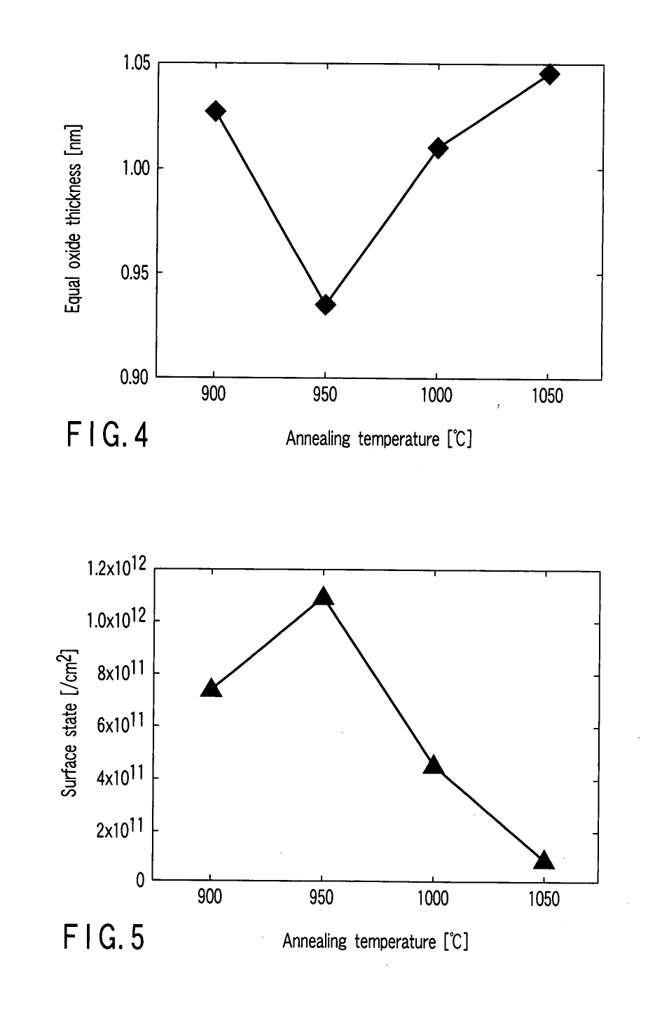

In the graph of showing a relationship between annealing temperature and equivalent oxide thickness in the above step (3), the horizontal axis indicates the annealing temperature [° C.] and the vertical axis indicates the equivalent oxide thickness [nm]. It is found that when the annealing temperature exceeds 1050° C., the equivalent oxide thickness of the FET of the first embodiment is greater than that (1.05 nm) of a conventional FET that is manufactured by a method not using any annealing process in FIG. 4. It is thus desirable that the annealing temperature should be 1050° C. or lower.

In FIG. 5 showing a relationship between annealing temperature and interface density in the above step (3), the horizontal axis indicates the annealing temperature [° C.] and the vertical axis indicates the interface density [/cm²]. As is well-known, it is desirable that the interface density should be small since the driving force increases and the reliability improves in FETs. As shown in FIG. 5, It is found that when the annealing temperature is lower than 1000° C., the interface state density of the FET of the first embodiment becomes smaller than that (4×10¹¹/cm²) of a conventional FET. It is thus desirable that the annealing temperature should be 1000° C. or higher.

The reason why the annealing time ranges from 0.1 msec to 10 msec when an FLA apparatus or an LA apparatus is used in the above step (3) will be described.

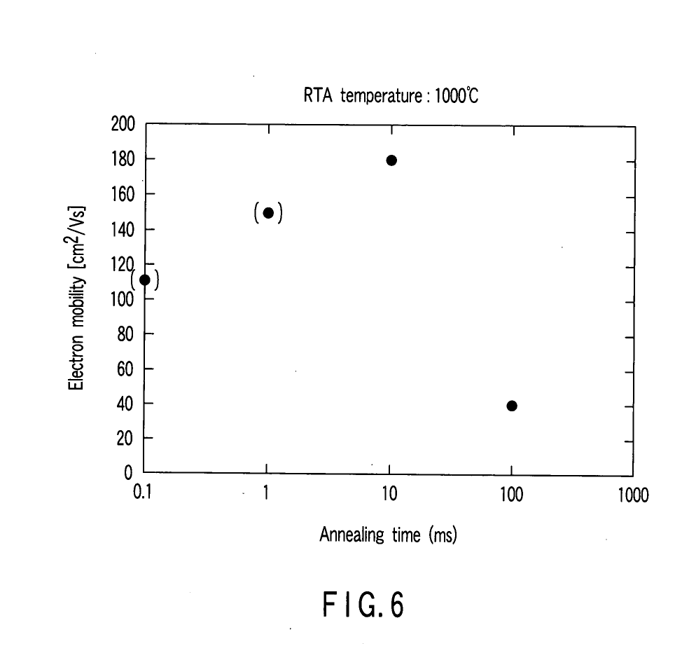

According to FIG. 6 showing a relationship between annealing temperature and electron mobility in the above step (3), the FLA apparatus is used as an annealing apparatus and the annealing temperature is set at 1000° C.

When the annealing time is as short as 0.1 ms, electron mobility of 110 cm²/Vs is obtained. As the annealing time becomes longer, the electron mobility increases, and electron mobility of 180 cm²/Vs is obtained when the annealing time is 10 ms. The electron mobility decreases suddenly when the annealing time exceeds 10 ms, and becomes 40 cm²/Vs when the annealing time is 100 ms. Even though the annealing time increases to 1150° C., almost the same advantage can be obtained. Even though the FLA apparatus is replaced with an LA apparatus, almost the same advantage can be obtained.

It is therefore desirable that the annealing time should be 0.1 sec to 10 sec when the FLA apparatus or LA apparatus is used.

According to the first embodiment, if annealing is performed immediately after the high dielectric film 105a is formed, it is possible to prevent a decrease in the equivalent oxide thickness of the gate insulating film due to the residual oxygen in the annealing apparatus by performing annealing after the polysilicon film 105b is formed on the high dielectric film 105a.

If the step (3) is replaced with a rapid thermal anneal step in which the annealing temperature ranges from 1000° C. to 1050° C., a semiconductor device whose electron mobility, gate leakage current, equivalent oxide thickness and interface state density are all improved more than those of a conventional device, can be achieved. Similarly, if the step (3) is replaced with a flash lamp anneal step or a laser anneal step in which the annealing time ranges from 0.1 msec to 10 msec, a semiconductor device whose electron mobility, gate leakage current, equivalent oxide thickness and interface state density are all improved more than those of a conventional device, can be achieved by short-time annealing.

Since annealing, which is conventionally performed immediately after a high dielectric film is formed, is done after the polysilicon film 105b is formed, no manufacturing costs are increased.

### Second Embodiment

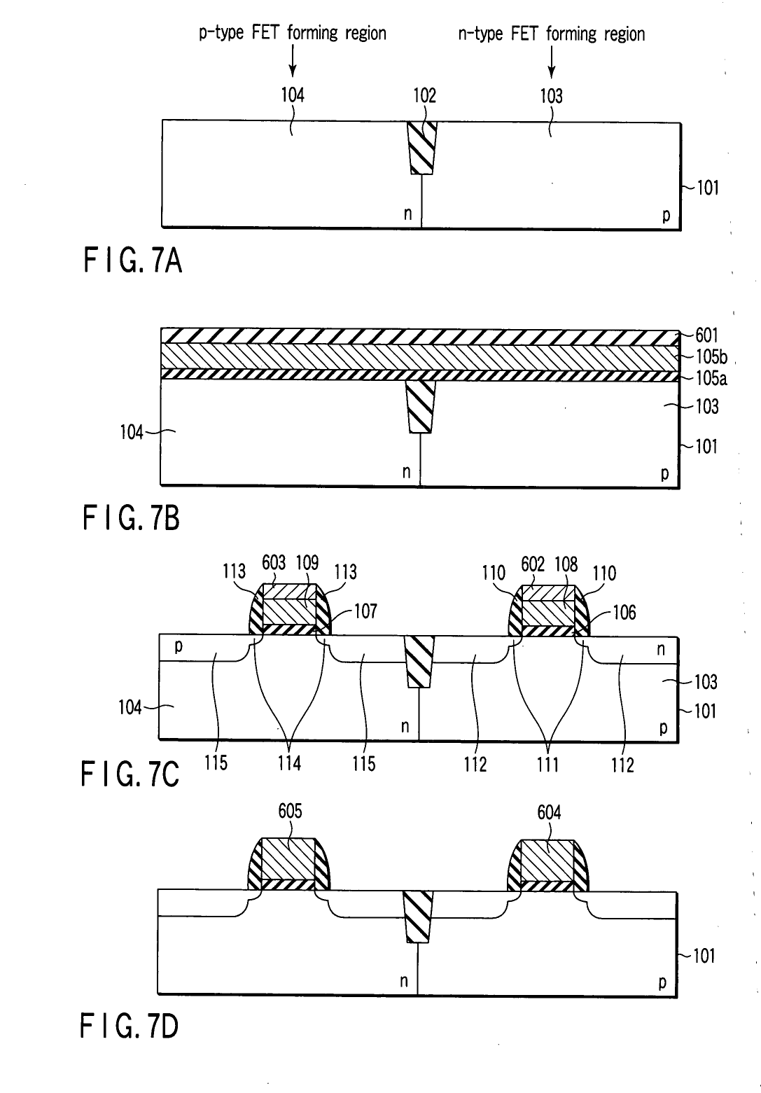

There will be described a process of manufacturing an MIS semiconductor device according to a second embodiment in FIGS. 7A to 7D. The same components as those of FIGS. 1A to 1D are denoted by the same reference numerals and their detailed descriptions are omitted.

(1) As shown in FIG. 7A, a shallow trench isolation (STI) region 102 is formed in a surface area of a semiconductor substrate 101 using a normal process technology. Then, impurities are introduced into the substrate to form a p-well (n-MISFET forming region) 103 and an n-well (p-MISFET forming region) 104, as in the first embodiment.

(2) And then, a high dielectric film 105a (e.g., HfAlO film) which is the same as that of the first embodiment is formed on the entire surface of the semiconductor substrate 101 in FIG. 7B. After that, a polysilicon film 105b is formed on the surface of the high dielectric film 105a. In the second embodiment, a hard mask film 601 (e.g., SiO₂ film and Si₃N₄ film) is formed on the surface of the polysilicon film 105b.

(3) Then, the semiconductor substrate 101 is annealed by a rapid thermal anneal (RTA) apparatus. As in the first embodiment, the annealing temperature is set at 1000° C. to 1050° C. and the annealing time is set at, for example, 10 to 30 sec. As in the first embodiment, a flash lamp anneal (FLA) apparatus and a laser anneal (LA) apparatus can be used for annealing at a temperature of, for example, 1000° C. to 1150° C. and for a time period of 0.1 msec to 10 msec.

(4) Then, a mask pattern (not shown) is formed by normal photolithography or the like and, as shown in FIG. 7C, the high dielectric film 105a, polysilicon film 105b and hard mask 601 are patterned by dry etching or the like. Thus, high dielectric gate insulating films 106 and 107, polysilicon gate electrodes 108 and 109, and hard mask patterns 602 and 603 are obtained.

(5) Then, the p-well 103 is doped with low-concentration n-type impurities to form an n-type extension region 111, and a sidewall 110 that covers either side of each of the high dielectric gate insulating film 106, polysilicon gate electrode 108 and hard mask pattern 602. After that, the p-well 103 is doped with high-concentration n-type impurities to form a high-concentration n-type impurity region 112.

Unlike in the first embodiment, the polysilicon gate electrodes 108 and 109 are not doped with impurities since the hard mask patterns 602 and 603 are formed.

Similarly, in the n-well 104, a sidewall 113 that covers either side of each of the high dielectric gate insulating film 107, polysilicon gate electrode 109 and hard mask pattern 603, a p-type extension region 114, and a high-concentration p-type impurity region 115 are formed.

(6) Activation annealing is performed for the semiconductor substrate 101 using an RTA apparatus, for example.

(7) The hard mask patterns 602 and 603 are removed and then an Ni film of, e.g., 80 nm is deposited. The resultant structure is heated at a temperature of, e.g., 400° C. to 500° C. for a suitable time period to make the polysilicon gate electrodes 108 and 109 into full silicide. If the ratio of the thickness of each of the polysilicon gate electrodes 108 and 109 to that of the Ni film is adjusted, the composition of the full silicide can be controlled and thus the threshold voltages of the gate electrodes can be set. Ni can be replaced with platinum, titanium, cobalt, tungsten, or the like.

(8) Then, for example, an unnecessary Ni film is removed to complete full-silicide gate electrodes 604 and 605 as shown in FIG. 7D.

In the method according to the second embodiment, annealing is performed at a temperature of 1000° C. to 1050° C. after the polysilicon film is formed on the high dielectric film. Therefore, a high-performance FET can be manufactured.

According to the second embodiment, since the hard mask patterns 602 and 603 are used, the polysilicon gate electrodes 108 and 109 are not doped with impurities in the above step (5). In the subsequent step, therefore, full-silicide gate electrodes 604 and 605 of good characteristics can be manufactured. Since the full-silicide gate electrodes 604 and 605 are used as a gate electrode, they are not depleted while the FET is operating, with the result that the FET can be improved in performance. Since, moreover, the full-silicide gate electrodes 604 and 605 are used, no impurities such as boron are diffused from the gate electrode into the semiconductor substrate. Consequently, the conditions for activation annealing and the nitrogen content of the high dielectric film can be determined without taking into consideration the diffusion.

The present invention is not limited to the first and second embodiments. In the above embodiments, HfAlO is used as a gate insulation film; however, the present invention is not always limited to HfAlO, but various metal oxide films can be used. For example, hafnium atoms can be replaced with lanthanum atoms, yttrium atoms, gadolinium atoms, or cesium atoms. As the gate insulating film, a high dielectric film whose dielectric constant is higher than that of a normal gate oxide film (SiO₂) can be used. The semiconductor substrate is not always limited to silicon, but various semiconductor substrates can be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing an MIS semiconductor device, comprising:
forming a high dielectric film on a main surface of a semiconductor substrate;
forming a silicon film on the high dielectric film;
annealing the semiconductor substrate after the silicon film is formed;
processing the high dielectric film and the silicon film into a gate pattern after the semiconductor substrate is annealed, to form a gate insulation film and a gate electrode; and
forming source and drain regions on the main surface of the semiconductor substrate using the gate electrode as a mask.

2. The method according to claim 1, wherein the annealing includes annealing the semiconductor substrate by rapid thermal annealing whose annealing temperature ranges from 1000° C. to 1050° C.

3. The method according to claim 1, wherein the annealing includes annealing the semiconductor substrate by flash lamp annealing whose annealing time ranges from 0.1 msec to 10 msec.

4. The method according to claim 1, further comprising forming a hard mask on the silicon film before the semiconductor substrate is annealed.

5. The method according to claim 1, wherein the high dielectric film is formed of a metal oxide film including Hf and Al, and the silicon film is polysilicon.

6. A method of manufacturing an MIS semiconductor device, comprising:
forming a high dielectric film as a gate insulating film on a main surface of a semiconductor substrate;
forming a silicon film on the high dielectric film;
forming a hard mask film on the high dielectric film;
annealing the semiconductor substrate after the hard mask film is formed;
processing the high dielectric film, the silicon film, and the hard mask film into a gate pattern after the semiconductor substrate is annealed, to form a laminated film including a gate insulator, a gate electrode, and a hard mask pattern;
forming source and drain regions by ion-implanting impurities into the main surface of the semiconductor substrate using the hard mask pattern as a mask;
removing the hard mask film after the source and drain regions are formed; and
making the gate electrode into silicide by metal atoms after the hard mask film is removed.

7. The method according to claim 6, wherein the annealing includes annealing the semiconductor substrate by rapid thermal annealing whose annealing temperature ranges from 1000° C. to 1050° C.

8. The method according to claim 6, wherein the annealing includes annealing the semiconductor substrate by flash lamp annealing whose annealing time ranges from 0.1 msec to 10 msec.

9. The method according to claim 6, wherein the high dielectric film is formed of a metal oxide film including Hf and Al, and the silicon film is polysilicon.

10. A method of manufacturing an MIS semiconductor device, comprising:
forming a high dielectric film on a main surface of a semiconductor substrate of a first conductivity type;
forming a silicon film on the high dielectric film;
annealing the semiconductor substrate after the silicon film is formed;
processing the high dielectric film and the silicon film into a gate pattern after the semiconductor substrate is annealed, to form a gate insulating film and a gate electrode; and
forming source and drain regions of a second conductivity type on the main surface of the semiconductor substrate by ion-implanting impurities into the main surface of the semiconductor substrate using the gate electrode as a mask.

11. The method according to claim 10, wherein the annealing includes annealing the semiconductor substrate by rapid thermal annealing whose annealing temperature ranges from 1000° C. to 1050° C.

12. The method according to claim 10, wherein the annealing includes annealing the semiconductor substrate by flash lamp annealing whose annealing time ranges from 0.1 msec to 10 msec.

13. The method according to claim 10, further comprising forming a hard mask on the silicon film before the semiconductor substrate is annealed.

14. The method according to claim 10, wherein the high dielectric film is formed of a metal oxide film including Hf and Al, and the silicon film is polysilicon.

15. An MIS semiconductor device manufactured by a process, comprising:
forming a high dielectric film on a main surface of a semiconductor substrate;
forming a silicon film on the high dielectric film;
annealing the semiconductor substrate after the silicon film is formed;
processing the high dielectric film and the silicon film into a gate pattern after the semiconductor substrate is annealed, to form a gate insulation film and a gate electrode; and
forming source and drain regions on the main surface of the semiconductor substrate using the gate electrode as a mask.

16. The device according to claim 15, wherein the annealing includes annealing the semiconductor substrate by rapid thermal annealing whose annealing temperature ranges from 1000° C. to 1050° C.

17. The device according to claim 15, wherein the annealing includes annealing the semiconductor substrate by flash lamp annealing whose annealing time ranges from 0.1 msec to 10 msec.

18. The device according to claim 15, further comprising forming a hard mask on the silicon film before the semiconductor substrate is annealed.

19. The device according to claim 15, wherein the high dielectric film is formed of a metal oxide film including Hf and Al, and the silicon film is polysilicon.
